(19) United States
(12) Patent Application Publication
(10) Pub. No.: US 2026/0247885 A1
(43) Pub. Date: Aug. 20, 2026

(54) LOCALIZED FILM STRESS MODULATION BY IMPLANT

(71) Applicant: Applied Materials, Inc., Santa Clara, CA (US)

(72) Inventors: Xiaodong Yang, Xi’an (CN); Scott Falk, Essex, MA (US); Rajesh Prasad, Lexington, MA (US); Lizhong Sun, San Jose, CA (US)

(73) Assignee: Applied Materials, Inc., Santa Clara, CA (US)

(21) Appl. No.: 19/159,883

(22) PCT Filed: Mar. 28, 2023
(86) PCT No.: PCT/CN2023/084495

§ 371 Date: Aug. 26, 2025

(51) Int. Cl. H10P 30/40; C23C 14/06; C23C 14/34; C23C 14/48; C23C 14/54; H10P 14/694; H10W 42/00

(52) U.S. Cl. CPC H10P 30/40; C23C 14/0617; C23C 14/34; C23C 14/48; C23C 14/54; H10P 14/69472; H10W 42/121

(57) ABSTRACT

Embodiments herein are directed to localized stress modulation via ion implant to a nitride film. In some approaches, a nitride film may be formed over a substrate, a metrology scan of the nitride film may be performed to measure stress information of the nitride film at a plurality of locations, and ions may be directed to the nitride film during an ion implant. A dose of the ion implant may vary across the nitride film based on the stress information of the nitride film at each of the plurality of locations.

### TECHNICAL FIELD

The disclosure relates to stress control in film layers and, more particularly, to localized stress modulation by ion implant to an aluminum nitride film.

### BACKGROUND

Devices such as integrated circuits, memory devices, and logic devices may be fabricated on a substrate such as a silicon wafer by a combination of deposition processes, etching, ion implantation, annealing, and other processes. Using a piezoelectric material for microelectromechanical systems (MEMS) is a well-known approach for creating electromechanical effects. Doped and undoped aluminum nitride (AlN) is one such type of material that is commonly used due to its ability to generate desirable piezoelectrical effects. Although AlN is a common material, due to its columnar structure, it can produce within-wafer (WiW) stress range of 60 MPa to 500 MPa, which can impede the performance of some MEMS systems, such as bulk acoustic wave (BAW) filters.

It is with respect to these and other considerations the present embodiments are provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In one embodiment, a method may include forming a nitride film over a substrate, performing a metrology scan of the nitride film to measure stress information of the nitride film at a plurality of locations, and directing ions to the nitride film during an ion implant, wherein a dose of the ion implant varies across the nitride film based on the stress information of the nitride film at each of the plurality of locations.

In another embodiment, a method of modifying stress in an aluminum nitride film, may include forming the aluminum nitride film over a substrate, performing a metrology scan of the nitride film to measure stress information of the aluminum nitride film at a plurality of locations, and directing ions to the aluminum nitride film during an ion implant, wherein a dose of the ion implant varies across the aluminum nitride film based on the stress information of the aluminum nitride film at each of the plurality of locations.

In another embodiment, an apparatus for film layer stress control may include a beam scanner operable to scan an ion beam with respect to a substrate, and a controller, coupled to the beam scanner, the controller including a processor and a memory unit coupled to the processor, including a scan routine, the scan routine operative on the processor to performing a metrology scan to an aluminum nitride film formed atop the substrate to determine stress information at each of a plurality of locations of the aluminum nitride film. The controller is further operable to generate a dose pattern based on the stress information determined for each of the plurality of locations of the aluminum nitride film, and direct ions to the aluminum nitride film during an ion implant, wherein a dose of the ion implant varies across the aluminum nitride film based on the dose pattern.

### BRIEF DESCRIPTION OF DRAWINGS

The accompanying drawings illustrate exemplary approaches of the disclosure, including the practical application of the principles thereof, as follows:

FIG. 1 depicts a side cross-sectional view of a device following deposition of a film layer, according to embodiments of the present disclosure;

FIG. 2A depicts a side cross-sectional view of the device during a wafer scan, according to embodiments of the present disclosure;

FIG. 2B depicts a top view of the device during the wafer scan, according to embodiments of the present disclosure;

FIG. 3 depicts a side cross-sectional view of the device during an ion implant, according to embodiments of the present disclosure;

FIG. 4 is a graph depicting a relationship between film stress and implant dose, according to embodiments of the present disclosure;

FIGS. 5A-5B depict different representations of an ion implanter, consistent with various embodiments of the disclosure; and

FIG. 6 is a flowchart illustrating a method, according to embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DESCRIPTION OF EMBODIMENTS

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so the disclosure will be thorough and complete, and will fully convey the scope of the subject matter to those skilled in the art. In the drawings, like numbers refer to like elements throughout.

The embodiments described herein relate to techniques and an apparatus/system for improved stress control in a film layer, such as an aluminum nitride (AlN) film layer deposited on a silicon wafer. As noted above, reducing the WiW stress range would help to improve BAW Filter performance. Prior art solutions for reducing within-wafer stress include modifying the film deposition recipe. This approach may be successful when the WiW stress range is 100 MPa or lower. However, embodiments of the present disclosure, can flatten stress profile range for a stress range greater than 100 MPa, which is advantageous in increasing device quality and yield. In the present disclosure, by applying a localized implant of, e.g., He+, B+, or N+ into an aluminum nitride film layer, wherein the aluminum nitride film may be approximately lum, the localized stress caused by the film layer can be modulated from tensile to compressive. In some non-limiting examples, a medium current implant tool may be used to modify such thick films using an appropriate energy and dose sufficient to achieve the desired stress change. In general, if the dose is increased, the stress decreases. Using a metrology tool and controller, which creates a localized dose pattern across the wafer, the within-wafer stress can be reduced as a result of the variable dose implant to create a more uniform amount of stress across the wafer.

Referring now to FIG. 1, a portion of a device 100 according to embodiments of the present disclosure will be discussed. Although non-limiting, the device 100 may represent part of a microelectromechanical system, such as a bulk acoustic wave (BAW) filter, including a substrate 102 (e.g., silicon). Although not shown, the device may further include a seed layer/metal film stack. The device 100 may further include a nitride film 104, such as a doped or undoped AlN film layer having an approximate thickness between 0.5-1.5 um, formed over the substrate 102 and seed layer/metal film stack. The nitride film 104 may be deposited directly atop an upper surface 106 of the substrate 102 using, for example, a physical vapor deposition (PVD) sputtering process.

As used herein, the term “physical vapor deposition (PVD)” refers to refers to a variety of vacuum deposition methods. Physical processes such as sputtering and evaporation are used in PVD to generate a vapor, in the form of atoms, molecules, or ions, of the coating material supplied from a target. They are then transported to and deposited on the substrate 102, resulting in coating formation. In some non-limiting PVD processes, the substrate temperature is substantially lower than the melting temperature of the target material, making it feasible to coat temperature-sensitive materials. PVD methods may use vacuum deposition in which the coating is deposited over the entire wafer surface simultaneously. Although not shown, the PVD sputtering process to form the nitride film 104 may be performed using a cluster tool known as the Endura® system, which is commercially available from Applied Materials, Inc. of Santa Clara, CA.

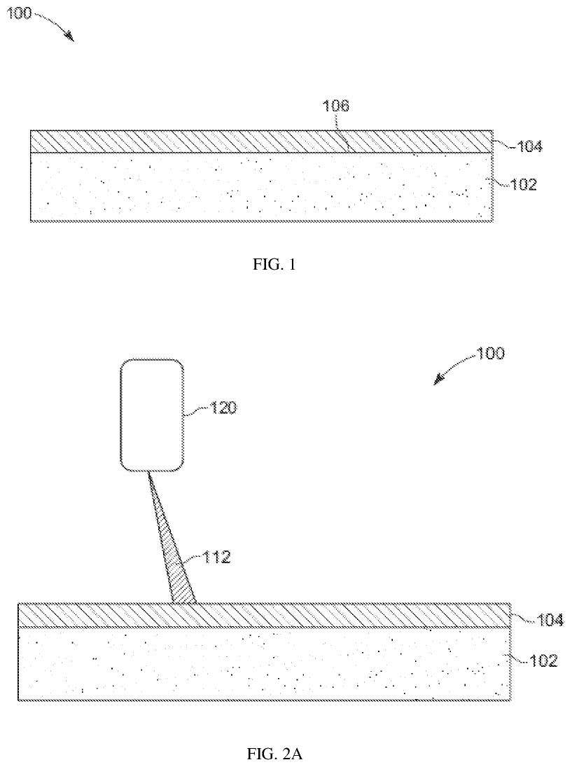

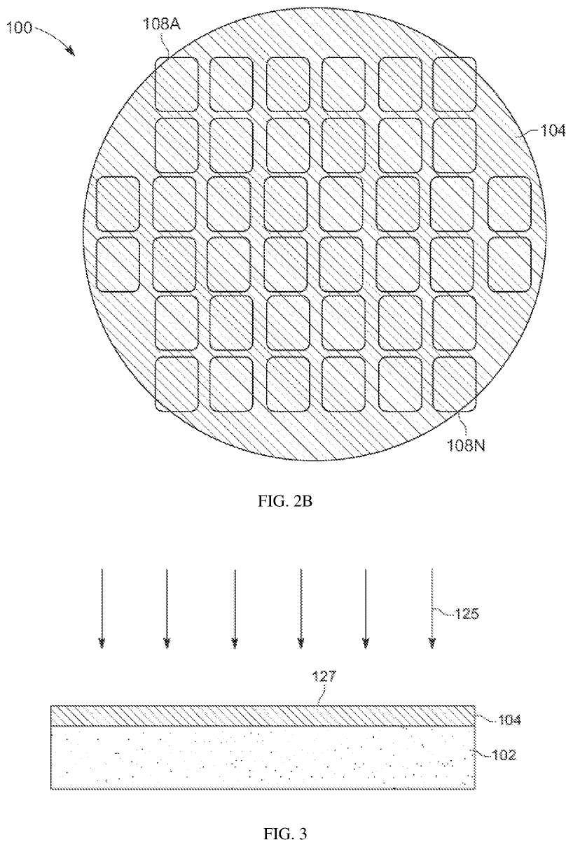

As shown in FIGS. 2A-2B , a metrology scan 112 may then be performed along the nitride film 104 to measure stress levels of the nitride film 104 at a plurality of locations 108A 108N (FIG. 2B). In some embodiments, the metrology scan may be performed by a film stress measurement (FSM) metrology tool 120 operable to measure stress across the diameter of the device 100 at a plurality of orientations (e.g., 5-10 orientations). The FSM metrology tool 120 may be further operable map the plurality of locations 108A-108N, which may be arranged uniformly across the nitride film 104, and to correlate the stress information to each of the plurality of locations 108A-108N. When the arrangement is consistent or uniform, the plurality of locations 108A-108N may be identifiable according to a grid or coordinate system. Stress information from the plurality of locations 108A-108N is used to generate a dose pattern, as will be described in greater detail below. In accordance with an example embodiment, the nitride film 104, as deposited, may have a tensile stress in one or more areas. In other embodiments, the nitride film 104 may have a neutral stress (zero stress) or compressive stress. In still other embodiments, the stress across the nitride film 104 may vary, and may include any combination of neutral, tensile, and/or compressive stresses. Although only a single layer is depicted, more than one nitride film layer may be present in alternative embodiments.

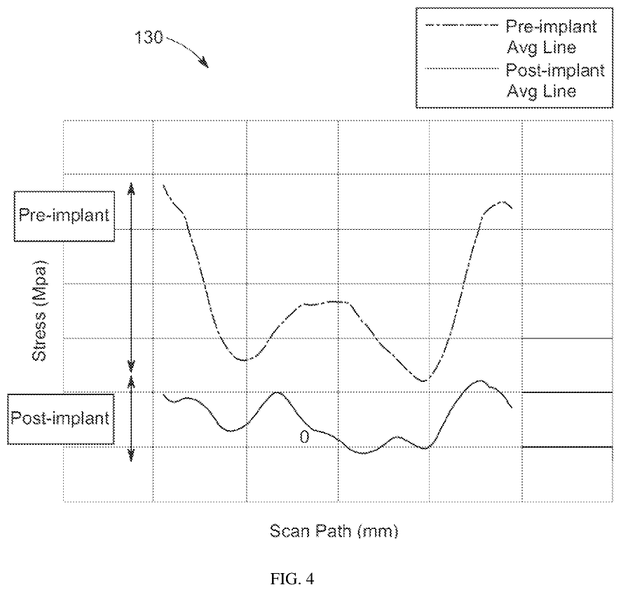

As shown in FIG. 3, an ion implant 125 (e.g., scanned spot or ribbon ion beam implant) may then be performed to direct ions into the nitride film 104. In the example shown, the ions may be B+, N+, or He+ ions, which are directed into an upper surface 127 of the nitride film 104 to locally modify stress in the nitride film 104 at one or more of the plurality of locations 108A 108N (FIG. 2B). In some embodiments, a dose pattern for the ion implant is generated based on the stress information determined for each of the plurality of locations 108A-108N of the nitride film 104. For example, the dose pattern may vary in proportion to the stress information detected at each of the plurality of locations 108A-108N. In general, the ion implant 125 provides a higher dose implant in those areas with higher stress, and provides lower dose implant in those areas with a relatively lower stress. Stated another way, the ions of the ion implant 125 may be implanted into a first location 108A of the plurality of locations at a first dose, and may be implanted into second location 108N of the plurality of locations at a second dose, wherein the first dose is greater than the second dose, and wherein a first stress value of the nitride film 104 measured at the first location 108A is greater than a second stress value of the nitride film 104 measured at the second location 108N. A non-limiting example of this relationship is demonstrated on a 200 mm wafer in graph 130 of FIG. 4. This relationship demonstrated may apply to different wafer sizes, for example, 150 mm, 200 mm, 300 mm, and so on. Using the dose pattern, which creates controlled dose variations across the nitride film 104 during implant, the within-wafer stress can be reduced to create a more uniform amount of stress across the device 100.

The dose pattern may further be influenced by local variations in film thickness and ion species. According to various embodiments, the ion energy of the ion implant 125 may be tuned to implant ions within an appropriate depth of the nitride film 104, in order to induce an adequate change in stress state. In some examples, the ions may be directed into the nitride film 104 at an energy of approximately 200-300 keV and with a dose in the range 1E13-1E15 using a medium current implant tool. Said differently, a dose ratio between a minimum dose value and a maximum dose value of the ion implant 125 may be between 6-10, preferably 8. Embodiments herein are not limited in this context, however, as the specific implant energy and dose values may vary.

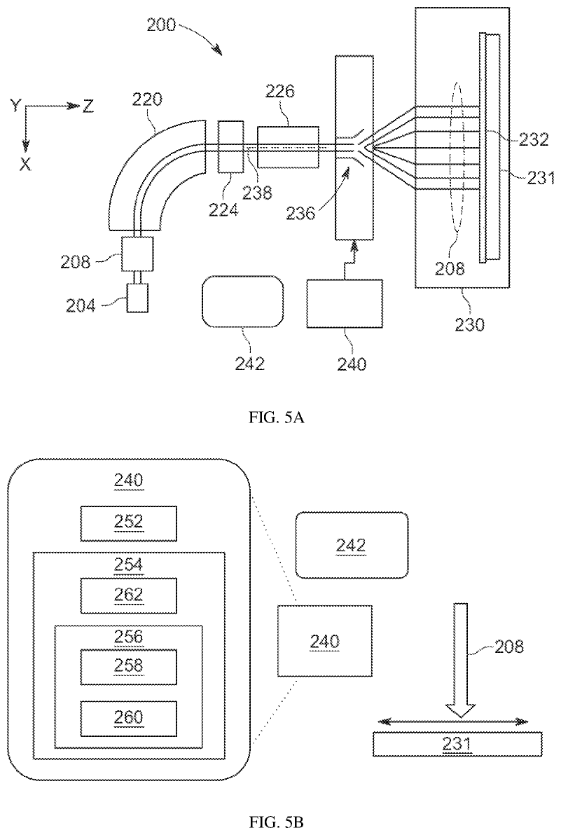

FIG. 5A depicts a schematic top view of an ion implantation system, or ion implanter 200, for stress control in accordance with embodiments of the disclosure. The ion implanter 200 represents a process chamber containing, among other components, an ion source 204 for producing an ion beam 208, and a series of beam-line components. The ion source 204 may include a chamber for receiving a flow of gas and generating ions. The ion source 204 may also include a power source and an extraction electrode assembly (not shown) disposed near the chamber. The beam-line components may include, for example, an analyzer magnet 220, a mass resolving slit (MRS) 224, a steering/focusing component 226, and end station 230, including substrate holder 231 and a substrate 232. Although the ion implanter 200 described herein is a medium-current (MC) ion implanter, it will be appreciated that a high-current (HC) ion implanter may also be used in alternative embodiments. It will be further appreciated that the substrate 232 may be the same or similar as the substrate 102 described herein.

The ion implanter 200 may further include a beam scanner 236 positioned along a beamline 238 between the MRS 224 and the end station 230. The beam scanner 236 may be arranged to receive the ion beam 208 as a spot beam, and to scan the ion beam 208 along a fast scan direction, such as parallel to the X-axis in the Cartesian coordinate system shown. Notably, the substrate 232 may be scanned along the Y-axis, so a given ion treatment may be applied to a given region of the substrate 232 as the ion beam 208 is simultaneously scanned back and forth along the X-axis. The ion implanter 200 may have further components, such as a collimator as known in the art (not shown for clarity), to direct ions of the ion beam 208, after scanning, along a series of mutually parallel trajectories to the substrate 232. In various embodiments, the ion beam 208 may be scanned at a frequency of several Hz, 10 Hz, 100 Hz, up to several thousand Hz, or greater. For example, the beam scanner 236 may scan the ion beam 208 using magnetic or electrostatic scan elements, as known in the art.

By scanning the ion beam 208 rapidly over a fast scan direction, such as back and forth over along the X-axis, the ion beam 208 may deliver a targeted ion dose of uniform density across a substrate 232. In accordance with various embodiments, the ion beam 208 may be controlled, responsive to user input, to generate a target implant pattern by a combination of scanning of the substrate 232 in conjunction with scanning of the ion beam 208.

For example, the ion implanter 200 may further include a controller 240, coupled to the beam scanner 236, to coordinate operation of the beam scanner 236 and substrate holder 231. As further shown in FIG. 5A, the ion implanter 200 may include a user interface 242, also coupled to the controller 240. The user interface 242 may be embodied as a display, and may include user selection devices, including touch screens, displayed menus, buttons, knobs, and other devices as known in the art. According to various embodiments, the user interface 242 may send instructions to the controller 240 to generate an appropriate implant pattern for the substrate 232 and a film layer (not shown) formed thereupon, according to the user input.

As further shown in FIG. 5B, the controller 240 may include a processor 252, such as a known type of microprocessor, dedicated processor chip, general purpose processor chip, or similar device. The controller 240 may further include a memory or memory unit 254, coupled to the processor 252, where the memory unit 254 contains a scan routine 256. The scan routine 256 may be operative on the processor 252 to manage scanning of the ion beam 208 and substrate 232 as described below. The memory unit 254 may comprise an article of manufacture. In one embodiment, the memory unit 254 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In particular embodiments, the scan routine 256 may include an implant pattern processor 258 and scan control processor 260. The implant pattern processor 258 may receive a set of substrate stress information, such as from host interface 242, indicative of the stress state in the film layer and/or the substrate 232. In some embodiments, the film layer is an AlN film layer. The implant pattern processor 258 may use the stress information to calculate an appropriate implant pattern to counter the film stress to create a more uniform amount of stress across the film layer and/or the substrate 232. The implant pattern information may include ion dose, ion species, implant energy, beam current, and implant tilt and/or twist. In various embodiments, a series of implant patterns may be stored in a database 262, where the different implant patterns may be correlated to different levels of stress across the film layer and/or the substrate 232. The scan control processor 260 may control scanning of the substrate 232, as well as scanning of the ion beam 208 to implement the implant pattern in the film layer and/or the substrate 232. Thus, in various embodiments, the treatment of the film layer using an implant pattern to generate a lower WiW stress range in the film layer may be automated, or partially automated.

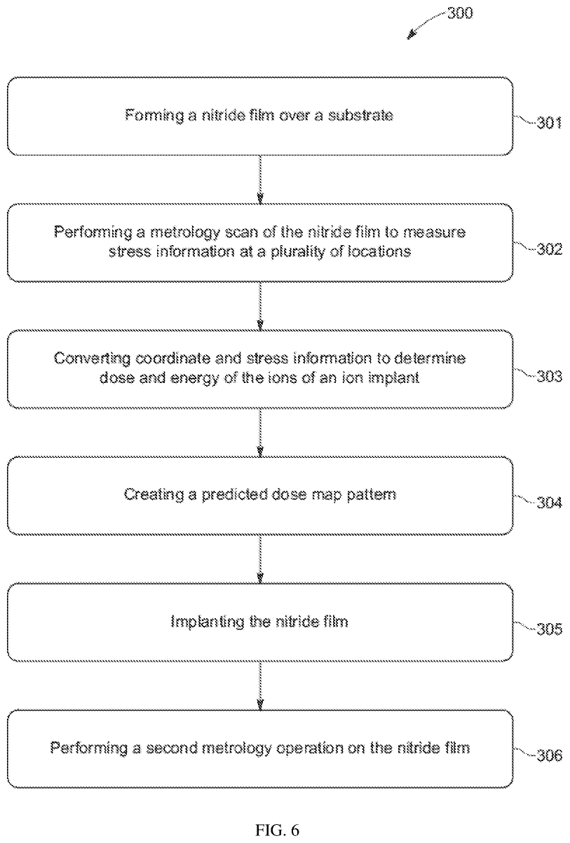

Referring to FIG. 6, a non-limiting method 300 according to embodiments of the present disclosure will be described. At block 301, the method 300 may include forming a nitride film over a substrate. In some embodiments, the nitride film may be an aluminum nitride film formed via PVD. In some embodiments, the aluminum nitride film is approximately lum thick, as measured from a top surface of the substrate. In some embodiments, the substrate is made from silicon.

At block 302, the method 300 may include performing a metrology scan of the nitride film to measure stress information of the nitride film at a plurality of locations. In some embodiments, the stress is measured across the diameter of the wafer at six (6) or more orientations using an FSM metrology tool.

At block 303, the method 300 may include converting coordinate and stress information to determine dose and energy of the ions of an ion implant procedure to be subsequently performed. In some embodiments, the information may be used for stress correction based on a stress calibration input coupled with an algorithm that will map the stress pattern to the targeted implanter dose map pattern in x and y or circular coordinates.

At block 304, the method 300 may include creating a predicted dose map pattern using ion beam profile information, which is based on the determined dose and energy of the ions, as well as other recipe information. In some embodiments, the dose of the ion implant varies across the nitride film based on the stress information of the nitride film at each of the plurality of locations. In some embodiments, a graph may be created using a beam profiler operable to measure certain parameters associated with the ion beam, such as beam current as a function of position. Although non-limiting, the beam profiler may comprise one or more Faraday devices arranged in a linear manner. In another embodiment, the beam profile may be measured by a plurality of Faraday devices arranged in a two-dimensional array. The Faraday devices collect current, and the beam profiler is able to measure an amount of current collected by each Faraday device. A controller may take the information from the beam profiler and generate a desired dose implant pattern. This desired dose implant pattern may be stored in the non-transitory storage element as a two-dimensional array, where the value of each element in the array represents the desired dose at that particular position.

At block 305, the ion implant is performed to the nitride film. In some embodiments, the ion implant occurs using both horizontal and vertical scanning of the device using a spot beam or a ribbon beam. Although non-limiting, the scanning is performed according to the desired dose implant pattern, and can be a combination of electrostatic or magnetic and mechanical. In some embodiments, the ion implant includes implanting the ions into a first location of the plurality of locations at a first dose, and implanting the ions into a second location of the plurality of locations at a second dose, wherein the first dose is greater than the second dose, and wherein a first stress value of the aluminum nitride film measured at the first location is greater than a second stress value of the aluminum nitride film measured at the second location. In some embodiments, the ion implant is performed to reduce the local a stress level of the nitride film at one or more locations of the plurality of locations in response to the ions directed to the nitride film during the ion implant. In some embodiments, the ion implant includes directing at least one of the following ion species to the nitride film: B+, N+, or He+. It will be appreciated that other ions species may be employed in other embodiments.

At optional block 306, a second metrology operation may then be performed to the nitride film to further refine the algorithm and start the stress modification process over again.

In sum, embodiments herein provide stress modulation in doped and undoped AlN films by variable dose ion implantation. A first advantage provided by the improvements of the embodiments described herein is the reduction of the WiW stress range to <100 MPa. A second advantage provided by the improvements of the embodiments described herein is the lack of significant change to the crystalline columnar structure of the AlN, e.g., as determined by X-ray diffraction (XRD) analysis. A third advantage provided by the improvements of the embodiments described herein is the increased rate of film deposition of the PVD process, which increases wafer throughput.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The foregoing discussion has been presented for purposes of illustration and description and is not intended to limit the disclosure to the form or forms disclosed herein. For example, various features of the disclosure may be grouped together in one or more aspects, embodiments, or configurations for the purpose of streamlining the disclosure. However, it should be understood that various features of the certain aspects, embodiments, or configurations of the disclosure may be combined in alternate aspects, embodiments, or configurations. Moreover, the following claims are hereby incorporated into this Detailed Description by this reference, with each claim standing on its own as a separate embodiment of the present disclosure.

1. A method, comprising:
forming a nitride film over a substrate;
performing a metrology scan of the nitride film to measure stress information of the nitride film at a plurality of locations; and
directing ions to the nitride film during an ion implant, wherein a dose of the ion implant varies across the nitride film based on the stress information of the nitride film at each of the plurality of locations.

2. The method of claim 1, wherein the nitride film is an aluminum nitride film formed using physical vapor deposition sputtering.

3. The method of claim 2, further comprising modifying, based on the stress information, an energy of the ions directed to the aluminum nitride film for each of the plurality of locations.

4. The method of claim 3, further comprising:
implanting the ions into a first location of the plurality of locations at a first dose; and
implanting the ions into a second location of the plurality of locations at a second dose, wherein the first dose is greater than the second dose, and wherein a first stress value of the aluminum nitride film measured at the first location is greater than a second stress value of the aluminum nitride film measured at the second location.

5. The method of claim 1, further comprising reducing a within-wafer stress range of the nitride film by reducing a local stress level of the nitride film at one or more locations of the plurality of locations in response to the ions directed to the nitride film during the ion implant.

6. The method of claim 1, wherein the ion implant comprises scanning a spot beam or a ribbon beam across the nitride film along a first direction and a second direction.

7. The method of claim 1, wherein directing ions to the nitride film during the ion implant comprises directing at least one of the following ion species to the nitride film: B+, N+, or He+.

8. A method of modifying stress in an aluminum nitride film, the method comprising:
forming the aluminum nitride film over a substrate;
performing a metrology scan of the nitride film to measure stress information of the aluminum nitride film at a plurality of locations; and
directing ions to the aluminum nitride film during an ion implant, wherein a dose of the ion implant varies across the aluminum nitride film based on the stress information of the aluminum nitride film at each of the plurality of locations.

9. The method of claim 8, wherein the aluminum nitride film is formed using physical vapor deposition sputtering.

10. The method of claim 8, further comprising modifying, based on the stress information, an energy of the ions directed to the aluminum nitride film for each of the plurality of locations.

11. The method of claim 10, further comprising:
implanting the ions into a first location of the plurality of locations at a first dose; and
implanting the ions into a second location of the plurality of locations at a second dose, wherein the first dose is greater than the second dose, and wherein a first stress value of the aluminum nitride film measured at the first location is greater than a second stress value of the aluminum nitride film measured at the second location.

12. The method of claim 8, further comprising reducing a local stress level of the aluminum nitride film at one or more locations of the plurality of locations in response to the ions directed to the aluminum nitride film during the ion implant.

13. The method of claim 8, wherein the ion implant comprises scanning a spot beam or a ribbon beam across the aluminum nitride film along a first direction and a second direction.

14. The method of claim 8, wherein directing ions to the aluminum nitride film during the ion implant comprises directing at least one of the following ion species into the nitride film: B+, N+, or He+.

15. An apparatus for film layer stress control, comprising:
a beam scanner operable to scan an ion beam with respect to a substrate; and
a controller, coupled to the beam scanner, the controller comprising:
a processor; and
a memory unit coupled to the processor, including a scan routine, the scan routine operative on the processor to performing a metrology scan to an aluminum nitride film formed atop the substrate to determine stress information at each of a plurality of locations of the aluminum nitride film, wherein the controller is further operable to:
generate a dose pattern based on the stress information determined for each of the plurality of locations of the aluminum nitride film; and
direct ions to the aluminum nitride film during an ion implant, wherein a dose of the ion implant varies across the aluminum nitride film based on the dose pattern.

16. The apparatus for film layer control according to claim 15, wherein the controller is further operable to form the aluminum nitride film using physical vapor deposition sputtering.

17. The apparatus for film layer stress control according to claim 15, wherein the controller is further operable to modify, based on the stress information, the dose and an energy of the ions directed to the aluminum nitride film for each of the plurality of locations.

18. The apparatus for film layer stress control according to claim 15, wherein directing ions to the aluminum nitride film during the ion implant comprises:
implanting the ions into a first location of the plurality of locations at a first dose; and
implanting the ions into a second location of the plurality of locations at a second dose, wherein the first dose is greater than the second dose, and wherein a first stress value of the aluminum nitride film measured at the first location is greater than a second stress value of the aluminum nitride film measured at the second location.

19. The apparatus for film layer stress control according to claim 15, wherein directing ions to the aluminum nitride film during the ion implant comprises directing at least one of the following ion species into the aluminum nitride film: B+, N+, or He+.
